(19) United States
(12) Patent Application Publication
(10) Pub. No.: US 2007/0262320 A1
(43) Pub. Date: Nov. 15, 2007

(54) ELECTRON EMITTER AND THE METHOD OF MANUFACTURING THE SAME APPARATUS

(75) Inventors: Yutaka HIROSE, Kyoto (JP); Shinichi TAKIGAWA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/617,060

(22) Filed: Dec. 28, 2006

(30) Foreign Application Priority Data
Jan. 19, 2006 (JP) 2006/011663

(51) Int. Cl. H01L 31/0312

(52) U.S. Cl. 257/77

(57) ABSTRACT

An electron emitter according to the present invention includes: an area in which a surface of the substrate is exposed or an area in which the inner surface of the substrate is exposed; the SiC substrate with the (0001) surface as a principal surface; the electron emission layer has carbon formed on the substrate surface C; and the electron formed on the area. In addition, the electrode may be formed on the substrate Si surface. Furthermore, the electron emission layer may be formed on a part of the substrate surface C. The electrode may be formed on the area, of the substrate C surface, on which the electron emission layer is not formed.

### BACKGROUND OF THE INVENTION

(1) Field of the Invention

The present invention relates to an electron emitter and its manufacturing method, and in particular relates to an electron emitter which includes an electron emission layer containing carbon, as a principal component, formed on a SiC substrate.

(2) Description of the Related Art

In recent years, a high power electron beam source using carbon nanotubes for a display, a high intensity emission apparatus and a high resolution electron microscope has been developed. (See the Non-Patent References 1 to 3 and Patent References 1 to 3). Since the carbon nanotubes allow high concentration of an electric field in a sharp-pointed tube end, compared to conventional materials, they are expected to realize high electron emission characteristics. However, there are technical problems in that plural tubes are needed to obtain a large amount of current output, and in that it is difficult to make the orientation of each tube end to be the same and grow it in the electron emission direction. In order to solve these problems, technologies for applying a method to electron emitters have been developed. The method includes: annealing, at a high temperature in a vacuum, a SiC substrate having a (0001) surface as a principal surface (hereinafter, referred to as the SiC substrate (0001) ), and making a high-orientation carbon nanotube array grow on the C surface of the SiC substrate (0001) (See the non-patent reference 4 and the patent references 4 and 5). The C surface of the SiC substrate (0001) refers to the surface determined by the SiC crystal polarity and represents the (000-1) surface. The Si surface of the SiC substrate, which is described below, refers to the surface determined by the SiC crystal polarity and represents the (0001) surface. In addition, it is known that the Si surface and the C surface of the SiC substrate have different chemical characteristics.

FIG. 1 is a schematic diagram illustrating a cross-sectional structure of a conventional electron emitter.

An electron emitter 300 shown in FIG. 1 includes the SiC substrate (0001) 11, a carbon nanotube layer 12, electrodes 14 and 18, a voltage source 15 and a carbon layer 16.

The carbon nanotube layer 12 is formed on the C surface of the substrate 11 (the upper side of the substrate 11 in FIG. 1) and has plural carbon nanotubes arrayed in perpendicular direction. The plural carbon nanotubes are formed by annealing the substrate 11 in vacuum.

The carbon layer 16 is a layer containing graphite as a principal component. The carbon layer 16 is formed on the Si surface of the substrate 11 (the lower side of the substrate 11 in FIG. 1) in the process of generating the carbon nanotube layer 12 (the process of annealing the substrate 11).

The electrode 14 is an electrode used as an anode and formed facing the carbon nanotube layer 12 across a gap 13. The electrode 18 is formed on the surface of the carbon layer 16. The voltage source 15 is connected between the electrode 14 and the electrode 18.

In the electron emitter 300, when voltage is applied between the electrode 14 and the electrode 18 by the voltage source 15, electrons are emitted from the carbon nanotube layer 12 to the electrode 14.

However, in the conventional electron emitter 300, the carbon layer 16 and the substrate 11 form a schottky barrier. In addition, since the electrode 18 is formed on the carbon layer 16 surface, there will be a large voltage drop generated by series resistance between the carbon nanotube layer 12 and the electrode 18. This causes a decrease in the electron emission efficiency of the electron emitter 300.

[Patent Reference 1] Japanese Laid-Open Patent Application No. 2001-15077

[Patent Reference 2] Japanese Laid-Open Patent Application No. 2001-20071

[Patent Reference 3] Japanese Laid-Open Patent Application No. 2001-20072

[Patent Reference 4] Japanese Laid-Open Patent Application No. 10-265208

[Patent Reference 5] Japanese Laid-Open Patent Application No. 2002-293522

[Non-Patent Reference 1] Jean-Marc Bonard et al., Solid-State Electronics, Vol. 45, (2001), pp. 893-pp. 914.

[Non-Patent Reference 2] Hiroyoshi Tanaka et al., Japanese Journal Applied Physics, Vol. 43, (2003), pp. 864-pp. 867.

[Non-Patent Reference 3] Yahachi Saito, Kagaku Frontier 2, Carbon Nonotube-Nanodevice e no chosen—(Chemical Frontier 2, Challenge for Carbon Nanotube—Nanodevice) (Kazuyoshi Tanaka (Edition)), Chapter 13, p. 175-p. 184, Kagaku Dojin (Chemistry Magazine) (2001)

[Non-Patent Reference 4] Michiko Kusunoki, Kagaku Frontier 2, Carbon Nonotube-Nanodevice e no chosen—(Chemical Frontier 2, Challenge for Carbon Nanotube—Nanodevice) (Kazuyoshi Tanaka (Edition)), Chapter 5, p. 89-p. 98, Kagaku Dojin (Chemistry Magazine) (2001)

### SUMMARY OF THE INVENTION

The present invention aims to provide an electron emitter with a high electron emission efficiency.

To solve the above-mentioned problem, the electron emitter according to the present invention has a SiC substrate which includes an area in which the surface of the substrate is exposed or an area in which the inner surface of the substrate is exposed, a (0001) surface as a principal surface and, an electron emission layer containing carbon formed on the C surface, and an electrode formed on the above-mentioned area.

Accordingly, since an electrode is formed on the substrate without the carbon layer and the like, series resistance between the electron emission layer and the electrode can be reduced. Furthermore, since good ohmic characteristics can be obtained in the connection of the electrode and the SiC substrate, series resistance between the electron emission layer and the electrode can be reduced. Accordingly, the electron emitter in the present invention can achieve a high electron emission efficiency.

The electrode may be formed on the Si surface of the substrate.

Accordingly, good ohmic characteristics can be obtained in the connection of the electrode and the Si surface of the SiC substrate. Therefore, the electron emitter according to the present invention can achieve a high electron emission efficiency.

The electron emission layer may be formed on a part of the substrate surface C and the electrode may be formed on the area, of the substrate C surface, on which the electron emission layer is not formed.

Accordingly, good ohmic characteristics can be obtained in the connection of the electrode and the C surface of the SiC substrate. Therefore, the electron emitter according to the present invention can achieve a high electron emission efficiency.

Moreover, the substrate may have the concave area in which the inner surface of the substrate is exposed, and a part of the electrode may cover an area of the substrate including the above-mentioned area, in which the inner surface of the substrate is exposed.

Accordingly, since the contact area between the electrode and the SiC substrate increases, contact resistance can be reduced. The thickness of the SiC substrate between the electrode and the electron emission layer can also be reduced. Therefore, series resistance between the electron emission layer and the electrode can be reduced. Accordingly, the electron emitter according to the present invention can achieve a high electron emission efficiency.

The electrode may be formed on the side surface of the substrate.

Accordingly, good ohmic characteristics can be obtained in the connection of the electrode and the SiC side surface. Therefore, the electron emitter according to the present invention can achieve a high electron emission efficiency.

The substrate may be n-type.

This can improve the conductivity to the direction of electron emission from the SiC substrate. Moreover, in comparing the p-type and n-type substrates, using the n-type substrate makes it possible to achieve low ohmic resistance in the connection of the electrode and the SiC substrate. Accordingly, the electron emitter according to the present invention can achieve a high electron emission efficiency.

Materials forming the electrode may include Ni.

This allows the formation of the electrode which has low ohmic resistance to the n-type substrate, achieving low series resistance in the connection of the electrode and the SiC substrate. Accordingly, the electron emitter according to the present invention can achieve a high electron emission efficiency.

The manufacturing method according to the present invention is for manufacturing the electron emitter. The manufacturing method includes the step of forming an electron emission layer which has carbon on the substrate surface C by annealing the SiC substrate with the (0001) surface as a principal surface so as to eliminate Si; the step of removing a predetermined area of a carbon film which has carbon formed on the substrate Si surface; and the step of forming an electrode on the predetermined area of the substrate Si surface.

This allows the manufacturing of the electron emitter with the electrode directly connected to the Si substrate without the carbon layer and the like. Therefore, the election emitter manufactured by the manufacturing method according to the present invention can reduce series resistance between the electron emission layer and the electrode. Thus, good ohmic characteristics can be obtained in the connection of the electrode and the SiC substrate, and accordingly series resistance between the electron emission layer is and the electrode can be reduced. Accordingly, the electron emitter manufactured by the manufacturing method according to the present invention can achieve a high electron emission efficiency. In other words, the manufacturing method according to the present invention can manufacture the electron emitter with a high electron emission efficiency.

Accordingly, the present invention can provide the electron emitter with a high electron emission efficiency.

### FURTHER INFORMATION ABOUT TECHNICAL BACKGROUND TO THIS APPLICATION

Japanese Patent Application No. 2006-011663 filed on Jan. 19, 2006 is incorporated herein by reference.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing a cross-sectional structure of the conventional electron emitter.

FIG. 2 is a perspective view showing the structure of the electron emitter in a first embodiment.

FIG. 3 is a diagram showing a cross-sectional structure of the electron emitter in the first embodiment.

FIG. 4 is a diagram showing a manufacturing process of the electron emitter in the first embodiment.

FIG. 5 is a diagram showing current characteristic corresponding to the applied voltage of the electron emitter in the first embodiment.

FIG. 6 is a diagram showing a cross-sectional structure of a variation of the electron emitter in the first embodiment.

FIG. 7 is a perspective view showing the structure of the electron emitter in the second embodiment.

FIG. 8 is a diagram showing a cross-sectional structure of the electron emitter in the second embodiment.

FIG. 9 is a diagram showing a manufacturing process of the electron emitter in the second embodiment.

FIG. 10 is a diagram showing current characteristic corresponding to the applied voltage of the electron emitter in the second embodiment.

FIG. 11 is a diagram showing a cross-sectional structure of a variation of the electron emitter in the second embodiment.

FIG. 12 is a diagram showing a cross-sectional structure of the electron emitter which has the electrode formed on the substrate side surface.

### DESCRIPTION OF THE PREFERRED EMBODIMENTS

The embodiments of the electron emitter according to the present invention are described below in reference to the drawings.

### First Embodiment

In an electron emitter in the first embodiment, an electrode is formed on the area of the Si surface of a SiC substrate on which a carbon layer is removed. Accordingly, series resistance between the electrode and a carbon nanotube layer can be reduced. Therefore, the electron emitter with a high electron emission efficiency can be realized.

First, the structure of the electron emitter in this embodiment is described.

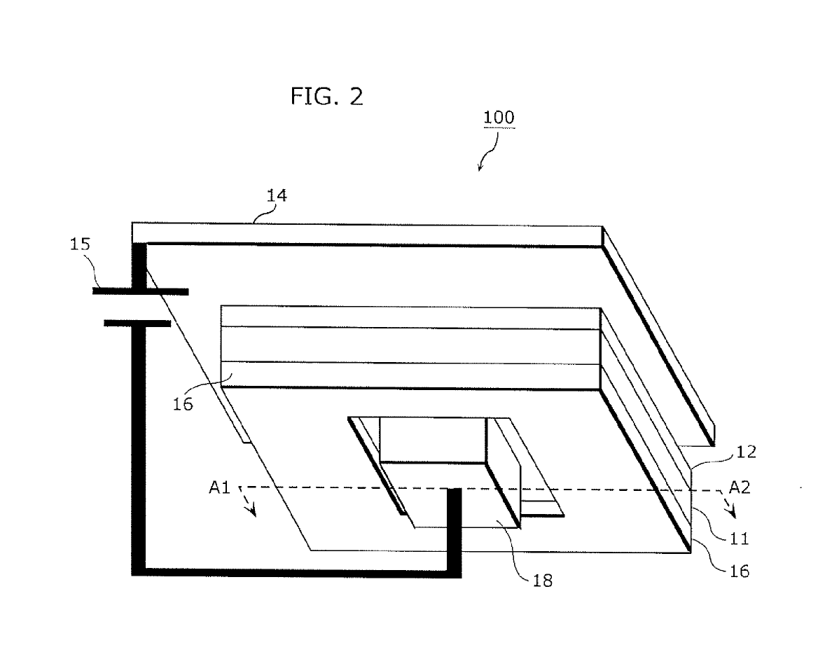

FIG. 2 is a perspective view showing the structure of the electron emitter in this embodiment.

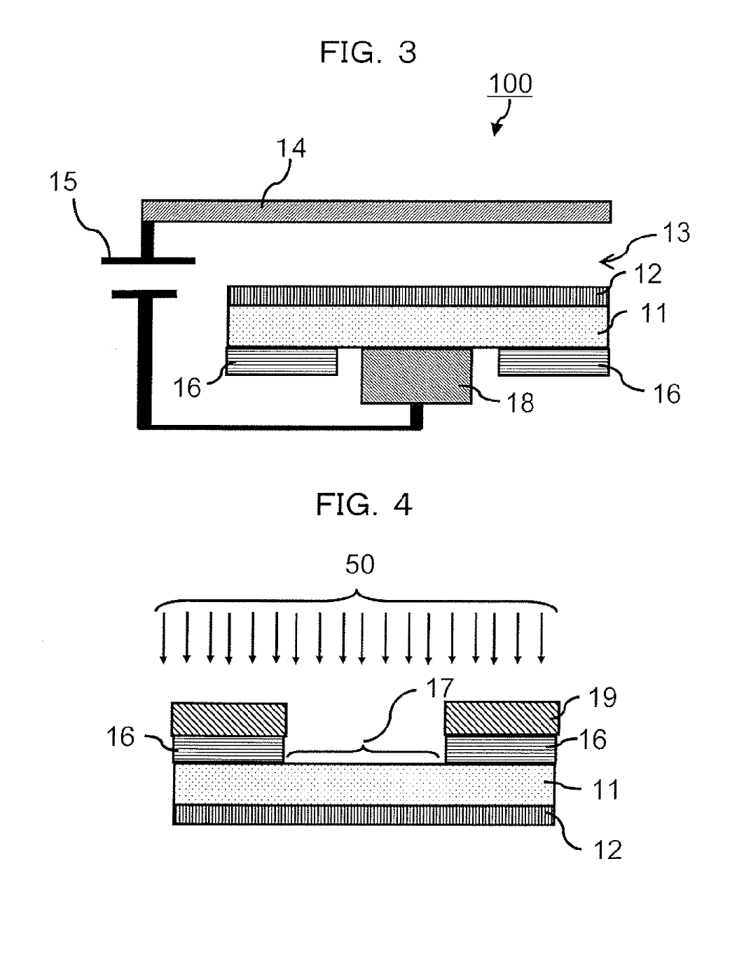

FIG. 3 is a schematic diagram illustrating a cross-sectional structure of the electron emitter sectioned along A1 to A2 in FIG. 2.

An electron emitter 100 shown in FIG. 2 and FIG. 3 includes a substrate 11, a carbon nanotube layer 12, electrodes 14 and 18, a voltage source 15, and a carbon layer 16.

The substrate 11 is a conductive 4H-n-type SiC substrate (0001).

The carbon nanotube layer 12 is an election emission layer which has plural carbon nanotubes arrayed in perpendicular direction and has carbon formed on the C surface of the substrate 11. For example, the thickness of the carbon nanotube layer 12 is approximately 200 nm. Each tube of the carbon nanotube layer 12 is a multi-wall type containing the five-layer carbon surface on average and approximately 110 nm diameter on average. Since the structure of each tube is closed on the top surface while keeping a distance between the respective carbon surfaces, each tube is formed to have a sharp-pointed tube end.

The carbon layer 16 is a layer containing carbon graphite, as a principal component, formed on the Si surface of the substrate 11.

An electrode 14 is an electrode used as an anode and is formed facing the carbon nanotube layer 12 across the gap 13 with an interval of 1 μm. The gap acts as a potential barrier.

The electrode 18 is a back surface electrode formed on the Si surface of the substrate 11 which is an area in which the raw material SiC of the substrate 11 is exposed. The electrode 18 is formed by the back surface electrode materials having Ni as a principal component.

The voltage source 15 is connected between the electrode 14 and the electrode 18.

In an electron emitter 300, when voltage is applied between the electrode 14 and the electrode 18 by the voltage source 15, electrons are emitted from the carbon nanotube layer 12 to the electrode 14.

Next, the manufacturing method of the electron emitter 100 in this embodiment is described.

The Si on the C surface of the SiC substrate 11 is eliminated by annealing the substrate 11 at a temperature of 1500 degrees Celsius in a vacuum of 1×10⁻⁵ Torr for 60 minutes. Accordingly, six-membered ring structures of the remaining carbon are connected and plural carbon nanotubes having hollow tube structures are formed. In other words, the carbon nanotube layer 12 which is the election emission layer containing carbon is formed.

Through the process of generating the carbon nanotube layer 12 (the process of annealing the substrate 11 at a temperature of 1500 degrees Celsius in a vacuum of 1×10⁻⁵ Torr for 60 minutes), Si of the Si surface of the substrate 11 is also eliminated. Since the substrate 11 is annealed in the state that it is placed on a pedestal or the like with the Si surface down, it is difficult to grow carbonnanotubes perpendicular to the Si surface. As a result, the carbon layer 16 mainly containing graphite is formed on the Si surface of the substrate 11. The electric conductivity of the carbon layer 16 is lower than that of pure metal, and the carbon layer 16 is not desirable for an ohmic contact, which needs low resistance, between the substrate 11 and the electrode 18. Therefore, in the manufacturing method of the election emitter 100 in this embodiment, a low resistance ohmic contact can be achieved by removing the carbon layer 16 and forming the electrode 18 on the area on which the carbon 16 is removed.

FIG. 4 is a diagram showing the process of removing the carbon layer 16 in the manufacturing process of the election emitter 100 in this embodiment.

As shown in FIG. 4, through an etching method using an Ar ion beam 50, the carbon layer 16 on an electrode formation area on the Si surface of the substrate 11 is removed, so as to form an area 17 in which SiC of the substrate 11 is exposed. After Ni (5000 Å) is deposited on the area 17, the electrode 18 is formed on the area 17 of the Si surface of the substrate 11 by annealing of 1100 degrees Celsius. Subsequently, the formed electrode 18 is connected to the voltage source 14. In this process, the Si surface area, on which the carbon layer 16 does not need to be removed, may be protected by a resist 19 as shown in FIG. 4 and the resist 19 may be removed with an organic cleaning solution after the etching is completed. For example, the resist 19 is formed by silicon oxide or silicon nitride or the like.

In this way, in the electron emitter 100 in this embodiment where annealing is performed after Ni is deposited on the Si surface of the substrate 11 without the carbon layer 16, the contact resistance between the substrate 11 and the electrode 18 becomes approximately 10⁻⁴ Ωcm² which is one digit lower than the one obtained in the case in which the electrode 18 is formed by accumulating Ni on the carbon layer 16.

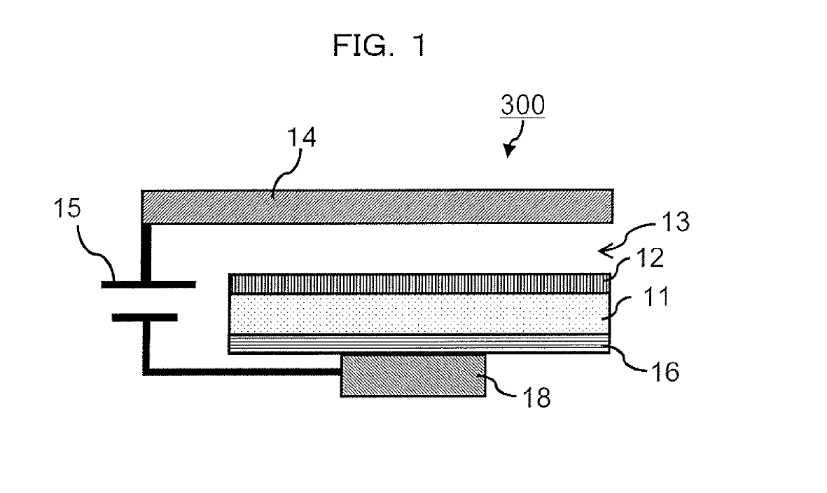

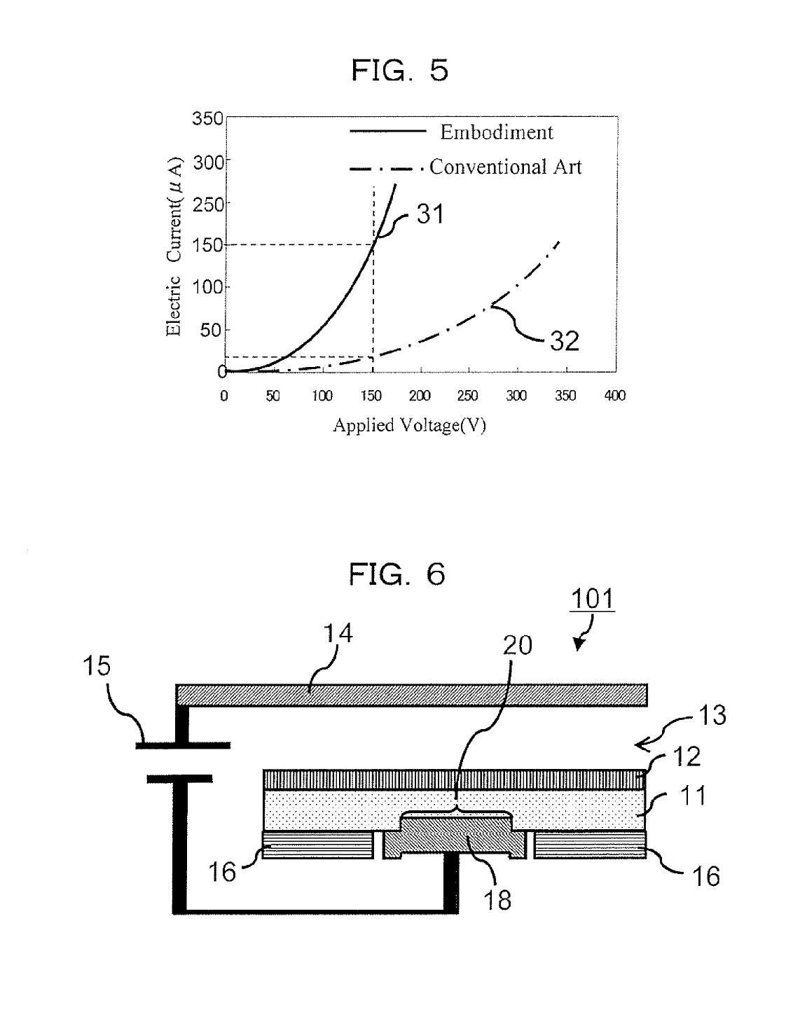

FIG. 5 is a diagram showing the emission electron current characteristic corresponding to the voltage applied from the voltage source 15 in the electron emitter 100. A curve 31 in FIG. 5 shows the emission electron current characteristic corresponding to the applied voltage in the election emitter 100 in this embodiment. A curve 32 shows the emission electron current characteristic corresponding to the applied voltage in the conventional electron emitter 300 where the electrode 18 is formed on the carbon layer 16 surface shown in FIG. 1.

As shown in FIG. 5, the electron emitter 100 in this embodiment can have large emission electron current compared to the conventional electron emitter 300 due to the low contact resistance between the substrate 11 and the electrode 18. For example, when comparing emission electron currents at an applied voltage of 150 V, the emission electron current of the electron emitter 100 in this embodiment is five times or more than that of the conventional electron emitter 300. In other words, the electron emitter 100 in this embodiment can achieve a high electron emission efficiency.

FIG. 6 is a schematic diagram illustrating a cross-sectional structure of a variation of the electron emitter 100 in this embodiment.

In the substrate 11 of an electron emitter 101 shown in FIG. 6, the carbon layer 16 on the area of Si surface is removed so as to form a concave area 20 in which the inner surface of the substrate 11 is exposed. The electrode 18 is formed to be embedded in the concave area 20. In other words, the electrode 18 is formed to cover the area 20. After the carbon layer 16 is removed as shown in FIG. 4, the area 17 on the SiC substrate 11 is etched so as to form the area 20 on which a remaining carbon layer is completely controlled not to grow.

Since the electron emitter 101 can also make the electrode materials adhere to the side surface perpendicular to the Si surface, of the substrate 11, which has been exposed by etching, the contact area between the electrode 18 and the substrate 11 increases and the low contact resistance (5×10⁻⁵ Ωcm² or below) can be achieved. Moreover, since the thickness of the SiC substrate between the carbon nanotube layer 12 and the electrode 18 decreases, series resistance between the carbon nanotube layer 12 and the electrode 18 can be reduced. Therefore, a high electron emission efficiency can be achieved.

Accordingly, in the manufacturing method of the electron emitter 100 in this embodiment, the carbon nanotube layer 12 is formed on the C surface of the substrate 11 by annealing the substrate 11 and eliminating Si. The carbon layer 16 formed on the Si surface of the substrate 11 by the annealing is removed by etching. Next, the electrode 18 is formed on the area 17 where the carbon layer 16 is removed. Accordingly, the electrode 18 in the electron emitter 100 is formed, without the carbon layer 16, on an area in which the raw material SiC of a surface of the substrate 11 is exposed or on an area in which the raw material SiC of an inner surface of the substrate 11 is exposed. Therefore, in the electron emitter 100 in this embodiment, series resistance between the carbon nanotube layer 12 and the electrode 18 can be reduced. Accordingly, the electron emitter 100 in the present invention can achieve a high electron emission efficiency.

Furthermore, by depositing Ni on the area in which SiC of the substrate 11 is exposed and annealing the SiC substrate 11, good ohmic characteristics can be obtained in the connection of the electrode 18 and the SiC substrate 11. Therefore, series resistance between the carbon nanotube layer 12 and the electrode 18 can be reduced. Accordingly, the electron emitter in the present invention can achieve a high electron emission efficiency.

In addition, in the electron emitter 101 in this embodiment, the electrode 18 is formed on the concave area in which the inner surface of the substrate 11 is exposed. Accordingly, since the contact area between the electrode 18 and the substrate 11 increases, contact resistance can be reduced. Moreover, since the thickness of the SiC substrate between the carbon nanotube layer 12 and the electrode 18 decreases, series resistance between the carbon nanotube layer 12 and the electrode 18 can be reduced. Therefore, a high electron emission efficiency can be achieved.

### Second Embodiment

In an electron emitter in the second embodiment, an electrode is formed on the C surface of a substrate 11, on which a carbon nanotube layer 12 is formed. Accordingly, series resistance between the electrode and the carbon nanotube layer 12 decreases and the electron emitter with a high electron emission efficiency can be realized.

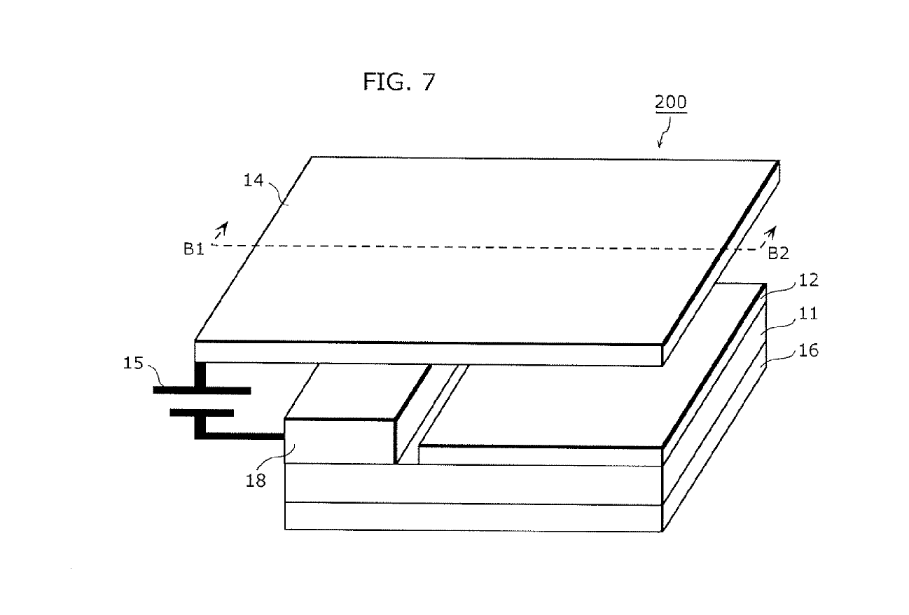

FIG. 7 is a perspective view showing the structure of the electron emitter in the second embodiment.

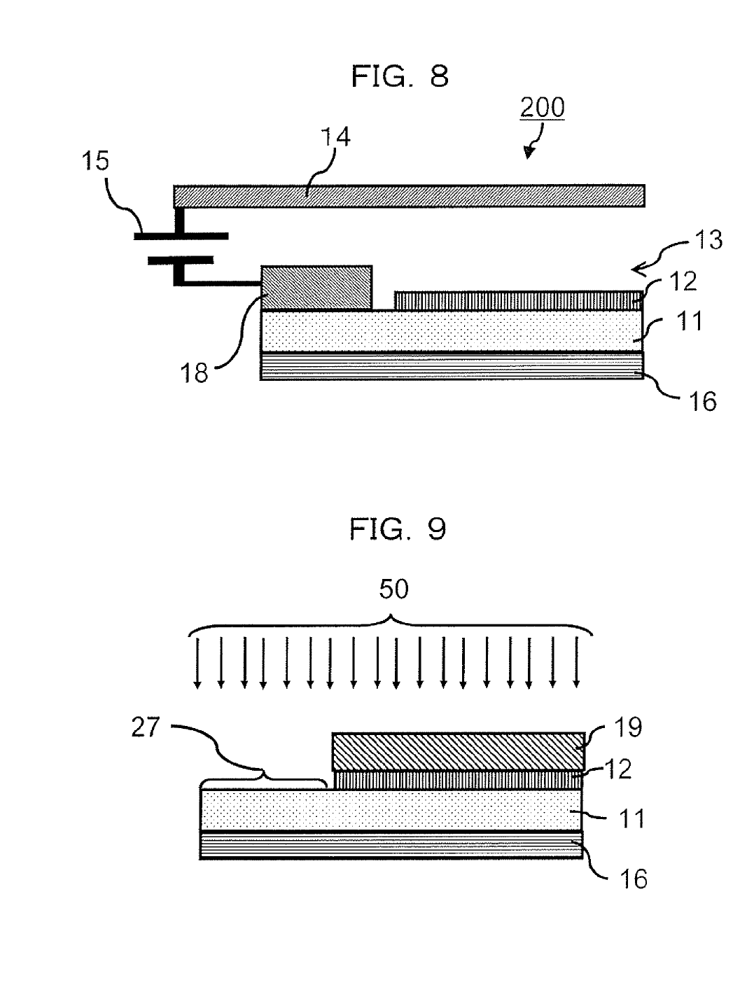

FIG. 8 is a schematic diagram illustrating a cross-sectional structure of the electron emitter sectioned along B1 to B2 in FIG. 7. The same reference numbers as the elements in FIG. 3 are provided and overlapped descriptions are omitted.

An electron emitter 200 shown in FIG. 7 and FIG. 8 is different from the electron emitter 100 in the first embodiment in that the electron emitter 200 includes an electrode 18 formed on the C surface of the substrate 11. Additionally, the carbon nanotube layer 12 is formed on a part of the C surface of the substrate 11, The electrode 18 is formed on the area of the C surface of the substrate 11, on which the carbon nanotube layer 12 is not formed.

The following is a description about the manufacturing method of the electron emitter in the second embodiment. The process until the carbon nanotube layer 12 is formed is omitted because the process is the same as that of the first embodiment.

FIG. 9 is a diagram showing the removal process of the carbon nanotube layer 12 in the electron emitter 200 in the second embodiment.

As shown in FIG. 9, through an etching method using an Ar ion beam 50, the carbon nanotube layer 12 on an electrode formation area 27 on the C surface of the substrate 11 is selectively removed. After Ni (5000 Å) is deposited on the area 27 where the carbon nanotube layer 12 is removed and accordingly SiC is exposed, the substrate 11 is annealed at a temperature of 1100 degrees Celsius. This allows the formation of the electrode 18. In this process, the area functions as the electron emission layer from the carbon nanotube layer 12 may be protected by a resist 19 as shown in FIG. 9. The resist 19 may be removed with an organic cleaning solution after the etching is completed.

In this way, in the electron emitter 200 in the second embodiment where annealing is performed after Ni is deposited on the surface C of the substrate 11, the contact resistance between the substrate 11 and the electrode 18 becomes approximately 10⁻⁴ Ωcm² which is one digit lower than the case in which the electrode 18 is formed by accumulating Ni on the carbon layer 16.

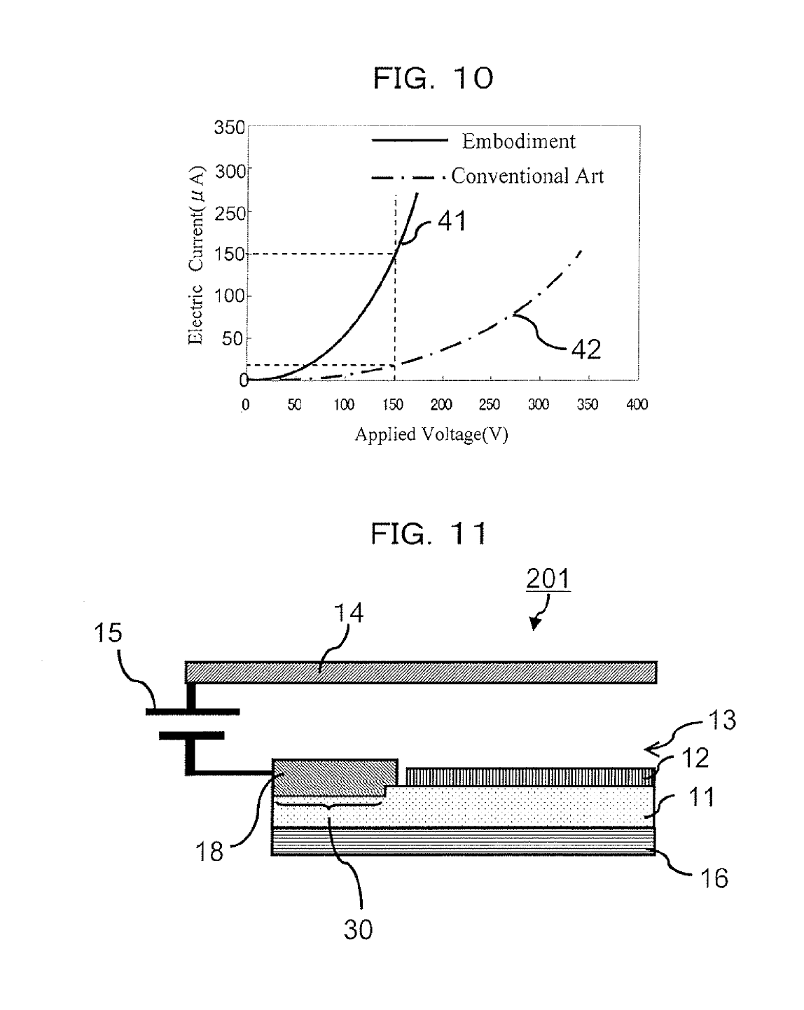

FIG. 10 is a diagram showing the emission electron current characteristic corresponding to the voltage applied from the voltage source 15 in the electron emitter 200. A curve 41 in FIG. 10 shows 25 the emission electron current characteristic corresponding to the applied voltage in the election emitter 200 in the second embodiment. A curve 42 shows the emission electron current characteristic corresponding to the applied voltage in the conventional electron emitter 300 where the electrode 18 is formed on the carbon layer 16 surface shown in FIG. 1.

As shown in FIG. 10, the electron emitter 200 in the second embodiment can have large emission electron current compared to the conventional electron emitter 300 due to the low contact resistance between the substrate 11 and the electrode 18. For example, when comparing emission electron currents at an applied voltage of 150 V, the emission electron current of the electron emitter 100 in this embodiment is five times or more than that of the conventional electron emitter 300. In other words, a high electron emission efficiency can be achieved.

FIG. 11 is a schematic diagram illustrating a cross-sectional structure of a variation of the electron emitter 200 in the second embodiment.

In the substrate 11 of an electron emitter 201 shown in FIG. 11, a concave area 30 is formed on the area of C surface, on which the carbon nanotube layer 12 is removed. The electrode 18 is formed to be embedded in the concave area 30. In other words, the electrode 18 is formed to cover the area 30. After the carbon layer 12 is removed as shown in FIG. 9, the area 27 on the SiC substrate 11 is etched so as to form the area 30 on which a remaining carbon layer is completely controlled not to grow.

Since the electron emitter 201 can also make the electrode materials adhere to the side surface perpendicular to the C surface, of the substrate 11, which has been exposed by etching, the contact area between the electrode 18 and the substrate 11 increases and the low contact resistance (5×10⁻⁵ Ωcm² or below) can be achieved. Therefore, a high electron emission efficiency can be achieved.

Accordingly, in the manufacturing method of the electron emitter 200 in this embodiment, the carbon nanotube layer 12 is formed on the C surface of the substrate 11 by annealing the substrate 11. A part of the carbon nanotube layer 12 formed on the C surface of the substrate 11 is removed by etching. The electrode 18 is formed on the area 27 where the carbon nanotube layer 12 has been removed. Accordingly, the electrode 18 in the electron emitter 200 is formed, without the carbon layer 16, on the area 27 in which the raw material SiC of a surface of the substrate 11 is exposed or the area 27 in which the raw material SiC of an inner surface of the substrate 11 is exposed. Therefore, in the electron emitter 200 in the second embodiment, series resistance between the carbon nanotube layer 12 and the electrode 18 can be reduced. Accordingly, the electron emitter 200 in this embodiment can achieve a high electron emission efficiency.

Furthermore, by depositing Ni on the area in which SiC is exposed and annealing the SiC substrate 11, good ohmic characteristics can be obtained in the connection of the electrode 18 and the SiC substrate 11. Therefore, series resistance between the carbon nanotube layer 12 and the electrode 18 can be reduced. Accordingly, the electron emitter 200 in this embodiment can achieve a high electron emission efficiency.

In addition, the electron emitter 201 in this embodiment forms the electrode 18 an the concave area in which the inner surface of the substrate 11 is exposed. Accordingly, since the contact area between the electrode 18 and the SiC substrate 11 increases, contact resistance can be reduced. Therefore, a high electron emission efficiency can be achieved.

The electron emitter and its manufacturing method in this embodiment according to the present invention have been described so far, but the present invention is not limited to these embodiments.

For example, in the above-mentioned description, the Ar ion beam 50 is used and the carbon layer 16 or the carbon nanotube layer 12 is etched, but the present invention is not limited to this. For example, oxygen plasma etching may be performed by changing the material and thickness of the resist.

In addition, in the above-mentioned description, a part of the carbon layer 16 is removed and the electrode 18 is formed on the removed area in the first embodiment, but the present invention is not limited to this. For example, all of the carbon layer 16 formed on the Si surface of the substrate 11 may be removed by etching without using the resist 19. Moreover, all of the carbon layer 16 formed on the Si surface of the substrate 11 may be removed by grinding rather than etching. Furthermore, in the case where all of the carbon layer 16 formed on the Si surface of the substrate 11 is removed, the electrode 18 may be formed on the whole area or a part of the Si surface of the substrate 11.

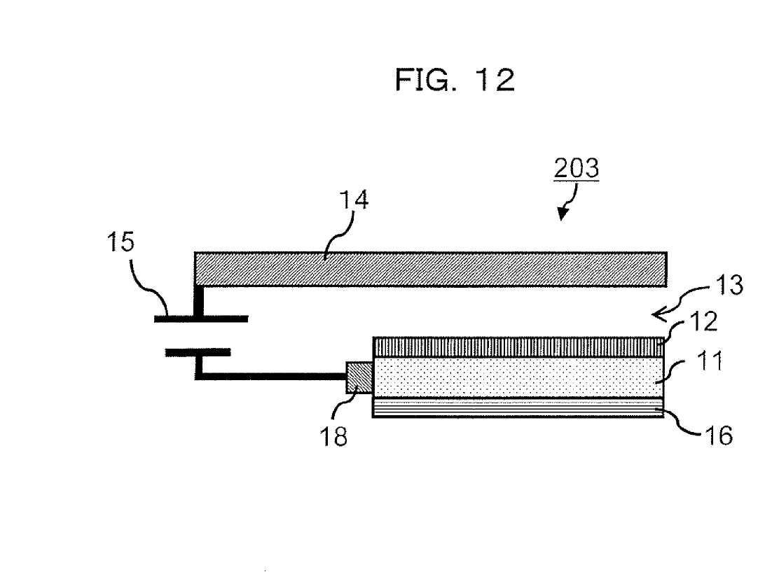

The electrode 18 may be formed on the substrate 11 side surface (perpendicular to the Si surface and the C surface). For example, after the substrate 11 is annealed so as to form the carbon nanotube layer 12 (and the carbon layer 16), the substrate 11 is cut and the electrode 18 is formed on the cut surface (perpendicular to the Si surface and the C surface). Accordingly, the electrode 18 can be formed on the area in which SiC of a side surface of the substrate 11 is exposed. FIG. 12 is a schematic diagram illustrating a cross-sectional structure of an electron emitter 202 that includes the electrode 18 formed on the side surface of the substrate 11. As shown in FIG. 12, the electrode 18 may be formed on the area in which SiC of a side surface of the SiC substrate 11 is exposed Accordingly, like the above-mentioned first and second embodiments, series resistance between the carbon nanotube layer 12 and the electrode 18 can be reduced. Therefore, the electron emitter 202 can achieve a high electron emission efficiency.

Although the present invention has been fully described by way of examples with reference to the accompanying drawings, it is to be noted that various changes and modifications will be apparent to those skilled in the art.

Therefore, unless otherwise such changes and modifications depart from the scope of the present invention, they should be construed as being included therein.

### INDUSTRIAL APPLICABILITY

The present invention can be applied to the electron emitter and its manufacturing method, and in particular, applied to a display using the electron emitter, a high intensity emission apparatus and a high resolution electron microscope and the like.

What is claimed is:

1. An electron emitter comprising:
a SiC substrate which has an area in which a surface of said substrate is exposed or an area in which an inner surface of said substrate is exposed, and a (0001) surface as a principal surface;
an electron emission layer containing carbon which is formed on a C surface of said substrate; and
an electrode which is formed on the area.

2. The electron emitter according to claim 1,
wherein said electrode is formed on the Si surface of said substrate.

3. The electron emitter according to claim 2,
wherein said substrate includes a concave area including the area in which the inner surface of said substrate is exposed, and
a part of said electrode covers the area in which the inner surface of said substrate is exposed.

4. The electron emitter according to claim 1,
wherein said electron emission layer is formed on a part of the C surface of said substrate, and
said electrode is formed on an area of the C surface of said substrate, the area on which said electron emission layer is not formed.

5. The electron emitter according to claim 4,
wherein said substrate includes a concave area including the area in which the inner surface of said substrate is exposed, and
a part of said electrode covers an area in which the inner surface of said substrate is exposed.

6. The electron emitter according to claim 1,
wherein said substrate includes a concave area including the area in which the inner surface of said substrate is exposed, and
a part of said electrode covers an area in which the inner surface of said substrate is exposed.

7. The electron emitter according to claim 1,
wherein said electrode is formed on a side surface of said substrate.

8. The electron emitter according to claim 1,
wherein said substrate is n-type.

9. The electron emitter according to claim 1,
wherein said electrode contains Ni.

10. A manufacturing method of an electron emitter comprising:
forming an electron emission layer containing carbon, on a C surface of a SiC substrate by annealing the substrate so as to eliminate Si, said substrate having a (0001) surface as a principal surface;
removing a predetermined area of a carbon film formed on a Si surface of said substrate by the annealing; and
forming an electrode on the predetermined area of the Si surface of said substrate.

11. A manufacturing method of an electron emitter comprising:
forming an electron emission layer containing carbon, on a C surface of a SiC substrate by annealing the substrate so as to eliminate Si, said substrate having a (0001) surface as a principal surface;
removing a predetermined area of the electron emission layer formed on a C surface of said substrate; and
forming an electrode on the predetermined area of the C surface of said substrate.
